(19) United States
(12) Patent Application Publication
(10) Pub. No.: US 2026/0239908 A1
(43) Pub. Date: Aug. 13, 2026

(54) METHOD FOR PROCESSING WORKPIECE AND METHOD FOR MANUFACTURING SEMICONDUCTOR DEVICE

(71) Applicant: DISCO CORPORATION, Tokyo (JP)

(72) Inventors: Yosuke Aoyagi, Tokyo (JP); Kenji Takenouchi, Tokyo (JP)

(21) Appl. No.: 19/453,465

(22) Filed: Jan. 20, 2026

(30) Foreign Application Priority Data
Feb. 13, 2025 (JP) 2025-021573

(51) Int. Cl. H10P 54/92; H10P 54/40

(52) U.S. Cl. CPC H10P 54/92; H10P 54/40

(57) ABSTRACT

A method for processing a workpiece is provided which can carry out proper hybrid bonding without causing an oxidation/etching phenomenon at a metal portion of a device even when the method includes cutting by a cutting blade. The method includes forming a protective film at the metal portion exposed at a surface of the workpiece, cutting by a cutting blade while supplying cutting water to the workpiece, and removing the protective film. At the forming the protective film, a protective film forming solution containing an anticorrosive is supplied, thereby forming a protective film on the metal portion.

### BACKGROUND

### 1. Technical Field

The present disclosure relates to a method for processing a workpiece, and a method for manufacturing a semiconductor device.

### 2. Description of the Related Art

In recent years, with a trend for higher integration of devices, hybrid bonding, in which two devices are directly bonded with each other, thereby connecting their electrodes, has started to be adopted. With the hybrid bonding, the surfaces of the devices are bonded together. For this reason, when foreign matters are deposited on the device surface, poor joining is undesirably caused. Under such circumstances, when hybrid bonding is carried out, as compared with joining via a conventional bump, there has been a still more eager demand for reduction of foreign matter deposition after division of a substrate for forming a device thereon.

Under such circumstances, in order to reduce foreign matter deposition after cut processing than in the prior art, the present applicant proposes a technology of carrying out washing of the surface side of a device by a washing fluid or a polishing pad. (see JP 2024-002148 A).

### SUMMARY

However, in a cutting, cutting water is supplied to the processing point at which a workpiece is cut by a cutting blade. For this reason, water falling on the metal portion exposed on the wafer surface and configuring an electrode causes an oxidation/etching phenomenon at the metal portion, resulting in a change in height of the metal portion. Accordingly, the electrodes are not connected with each other correctly with hybrid bonding, undesirably resulting in poor bonding.

The present disclosure was completed in view of the fact. It is a main technical object to provide a method for processing a workpiece and a method for manufacturing a semiconductor device, the methods being capable of carrying out proper hybrid bonding without causing an oxidation/etching phenomenon at the metal portion of a device even when the methods includes cutting by a cutting blade.

In order to solve the main technical problem, the present disclosure provides a method for processing a workpiece characterized by including forming a protective film on the metal portion exposed at the surface of the workpiece, cutting by a cutting blade while supplying cutting water to the workpiece, and removing the protective film, and characterized in that at the forming the protective film, the protective film is formed on the metal portion by supplying a protective film forming solution containing an anticorrosive.

The cutting and the forming the protective film may be carried out at the same time by including the protective film forming solution in the cutting water to be supplied to a processing point at the cutting. Further, the removing the protective film may be performed by polishing the surface of the workpiece by a polishing pad, thereby removing the protective film. Further, the removing the protective film may be performed by irradiating with a plasma to the surface of the workpiece, thereby removing the protective film.

Further, the present disclosure provides a method for manufacturing a semiconductor device, in which a substrate including devices respectively formed in regions partitioned by a plurality of crossing division lines is divided to form device chips, and then, the device surfaces are bonded with each other. The method includes: forming a protective film on a metal portion exposed on the device of the substrate; cutting the substrate by a cutting blade while supplying cutting water along the division lines of the substrate; grinding and thinning a surface of the substrate opposite to a surface on which the device is formed by a grinding wheel; removing the protective film; and bonding device surfaces of the device chip. The forming the protective film is performed by suppling a protective film forming solution containing an anticorrosive, and thereby forms a protective film on the metal portion of the device.

The method for processing a workpiece of the present disclosure is a method for processing a workpiece. The method includes forming a protective film on the metal portion exposed on the surface of the workpiece, cutting by a cutting blade while supplying cutting water to the workpiece, and removing the protective film. At the forming the protective film, the protective film is formed on the metal portion by supplying a protective film forming solution containing an anticorrosive. As a result, even when the method for processing a workpiece includes the cutting by the cutting blade, the workpiece can be processed so as to carry out proper hybrid bonding without causing the oxidation/etching phenomenon at the metal portion of the device.

Further, the method for manufacturing a semiconductor device of the present disclosure is a method for manufacturing a semiconductor device in which a substrate including devices respectively formed in regions partitioned by a plurality of crossing division lines is divided to form device chips, and then, the device surfaces are bonded with each other. The method includes: forming a protective film on a metal portion exposed on the device of the substrate; cutting the substrate by a cutting blade while supplying cutting water along the division lines of the substrate; grinding and thinning a surface of the substrate opposite to a surface on which the device is formed by a grinding wheel; removing the protective film; and bonding device surfaces of the device chip. The forming the protective film is performed by suppling a protective film forming solution containing an anticorrosive, and thereby forms a protective film on the metal portion of the device. Accordingly, even when the method for manufacturing a semiconductor device includes the cutting by the cutting blade, it is possible to manufacture a semiconductor device by carrying out proper hybrid bonding without causing an oxidation/etching phenomenon on the metal portion of the device.

### BRIEF DESCRIPTION OF THE DRAWINGS

FIG. 1 is a perspective view showing a wafer of a workpiece and an annular frame F ;

FIG. 2 is a cross sectional view showing a part schematically illustrating an embodiment of forming a protective film on an enlarged scale;

FIG. 3 is a partially enlarged cross sectional view showing an aspect in which a protective film is formed on a metal portion 121 of a device;

FIG. 4A is a perspective view showing an embodiment of cutting, and FIG. 4B is a partially enlarged cross sectional view of a wafer including cut grooves formed by the cutting therein;

FIG. 5A is an overall perspective view schematically showing a protective film removing apparatus and FIG. 5B is a side view, partly in section, schematically showing an embodiment of removing a protective film;

FIG. 6 is a side view, partly in section, schematically showing another embodiment of the removing the protective film;

FIG. 7 is a side view, partly in section, schematically showing a still other embodiment of the removing the protective film;

FIG. 8 is a perspective view schematically showing an embodiment of the grinding; and

FIG. 9 is a side view, partly in section, schematically showing an embodiment of a bonding.

### DESCRIPTION OF THE PREFERRED EMBODIMENTS

Below, embodiments in accordance with a method for processing a workpiece and a method for manufacturing a semiconductor device configured on the basis of the present disclosure will be described in details with reference to the accompanying drawings.

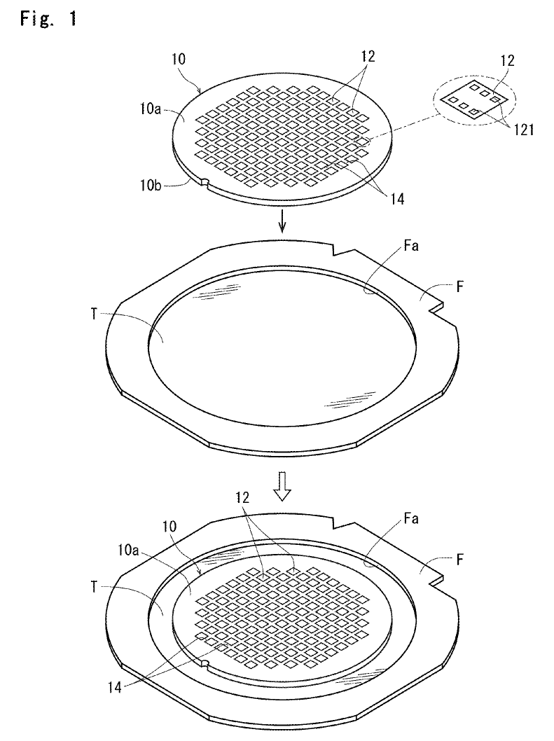

FIG. 1 shows a wafer 10 that is one example of a workpiece to be processed by the present disclosure. The wafer 10 is a substrate in which in a front surface 10a, devices 12 are respectively formed in respective regions partitioned by a plurality of crossing division lines 14. The shown substrate is the substrate of a semiconductor, and is formed of, for example, silicon (Si). However, the present disclosure is not limited thereto, and other semiconductor substrates are also acceptable, and for example, a substrate of SiC is also acceptable.

As understood from the enlarged perspective view of the device 12 shown on the right hand side of FIG. 1 (see the region surrounded by a dash-dotted line), a plurality of metal portions 121 each forming an electrode are exposed at the surface of the device 12. The metal portion 121 is formed of, for example, copper (Cu). Incidentally, the enlarged perspective view of the device 12 shown in FIG. 1 schematically shows the number and the arrangement positions of the metal portions 121 for convenience of description, and the present disclosure is not limited to the number and the array as shown. Further, the metal configuring the metal portion 121 is not limited to copper, and the metal portion 121 may be formed of, for example, nickel (Ni) or cobalt (Co).

For carrying out the method for processing a workpiece of the present embodiment, a frame F in an annular sheet shape having an opening Fa capable of accommodating the wafer 10 as shown in FIG. 1 is prepared. The wafer 10 is positioned with the front surface 10a facing upward at the center of the opening Fa, and a tape T having stickiness is bonded to the back surface of the frame F and the back surface 10b of the wafer 10, resulting in an integrated body, so that the wafer 10 is held by the frame F.

### Forming Protective Film

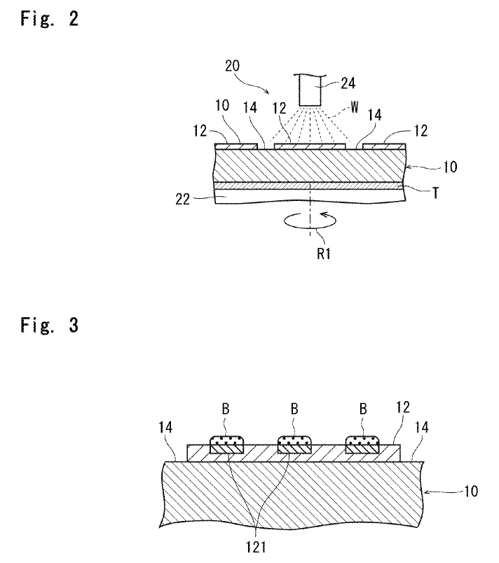

With the method for processing a workpiece of the present embodiment, first, forming a protective film on the metal portion 121 exposed at the front surface 10a of the wafer 10 is carried out. The forming the protective film is carried out by transporting the wafer 10 to a protective film forming apparatus 20 (only partially shown) shown in FIG. 2. The protective film forming apparatus 20 includes a chuck table 22 for holding the wafer 10, and rotatably configured, and a supply nozzle 24 connected with a protective film forming solution supply source not shown, and for supplying a protective film forming solution W toward the chuck table 22. The wafer 10 is transported to the protective film forming apparatus 20, and is mounted on the chuck table 22 to be sucked and held. Then, the supply nozzle 24 is positioned onto the wafer 10. Then, while rotating the chuck table 22 in a direction indicated with an arrow R1, the protective film forming solution W is added dropwise or sprayed from the supply nozzle 24. At this time, the supply nozzle 24 may be swung in the horizontal direction on the wafer 10. As a result of this, the protective film forming solution W is diffused on the front surface 10a of the wafer 10, and covers the metal portion 121 configuring the electrode on the device 12. As a result, as shown in FIG. 3, a protective film B is formed on the metal portion 121.

The protective film forming solution W is a liquid including a so-called anticorrosive, and is formed by, for example, allowing pure water to contain the anticorrosive exemplified below.

As the anticorrosive, for example, a heterocyclic aromatic compound having three or more nitrogen atoms per molecule, and, having a condensed ring structure, or a heterocyclic aromatic compound having four or more nitrogen atoms per molecule is preferably used. Further, an heterocyclic aromatic ring compound preferably includes a carboxyl group, a sulfo group, a hydroxy group, or an alkoxy group. Specifically, a tetrazole or a tetrazole derivative, a triazole or a triazole derivative, and a benzotriazole or a benzotriazole derivative are preferable. As a tetrazole derivative usable as an anticorrosive, mention may be made of the one not having a substituent on a nitrogen atom forming a tetrazole ring, and, introduced with an alkyl group substituted with at least one substituent selected from the group consisting of a sulfo group, an amino group, a carbamoyl group, a carbonamide group, a sulfamoyl group, and a sulfonamide group, or a substituent selected from the group consisting of a hydroxy group, a carboxy group, a sulfo group, an amino group, a carbamoyl group, a carbonamide group, a sulfamoyl group, and a sulfonamide group as a functional group included as the derivative.

Further, as a triazole derivative usable as an anticorrosive, mention may be made of the one not having a substituent on a nitrogen atom forming a triazole ring, and, introduced with an alkyl group or an aryl group substituted with at least one substituent selected from the group consisting of a hydroxy group, a carboxy group, a sulfo group, an amino group, a carbamoyl group, a carbonamide group, a sulfamoyl group, and a sulfonamide group, or a substituent selected from the group consisting of a hydroxy group, a carboxy group, a sulfo group, an amino group, a carbamoyl group, a carbonamide group, a sulfamoyl group, and a sulfonamide group, as the functional group included as a derivative.

Still further, as a benzotriazole derivative usable as an anticorrosive, mention may be made of the one not having a substituent on a nitrogen atom forming a benzotriazole ring, and, introduced with an alkyl group or an aryl group substituted with at least one substituent selected from the group consisting of a hydroxy group, a carboxy group, a sulfo group, an amino group, a carbamoyl group, a carbonamide group, a sulfamoyl group, and a sulfonamide group, or, a substituent selected from the group consisting of a hydroxy group, a carboxy group, a sulfo group, an amino group, a carbamoyl group, a carbonamide group, a sulfamoyl group, and a sulfonamide group as a functional group included as a derivative.

By supplying and diffusing the protective film forming solution W containing the above mentioned anticorrosive to the front surface 10a side of the wafer 10, a protective film B including a copper oxide(Cu₂O) film or a protective film B formed from one or more kinds of the anticorrosive components is formed on the metal portion 121 including Cu as shown in FIG. 3. Thus, the protective film B formed on the metal portion 121 is complexed. For this reason, even when a liquid containing water to be supplied in each procedure to be subsequently carried out comes in contact therewith, the protective film B will not be removed. Incidentally, the forming the protective film is not limited to the embodiment. For example, only by supplying the protective film forming solution W to the front surface 10a side of the wafer 10 without rotating the chuck table 22, the protective film B may be formed on the metal portion 121 of the device 12. Alternatively, by application to the front surface 10a of the wafer 10 using a known brush (pen brush or roller brush), or the like without using the protective film forming apparatus 20, the protective film B may be formed on the metal portion 121 of the device 12. Further, the concentration of the anticorrosive contained in the protective film forming solution W is preferably 0.1 ppm to 100 ppm, and further preferably 0.1 ppm to 10 ppm, for example, at a point to be in contact with the wafer 10 that is a workpiece. Setting within such a range results in the rapid formation of the protective film B on the metal portion 121, and prevents excessive use of the protective film forming solution W.

### Cutting

Provided that the forming the protective film is carried out, cutting the wafer 10 by a cutting blade while supplying cutting water to the wafer 10 is carried out. The cutting is carried out, for example, by the procedure as shown below.

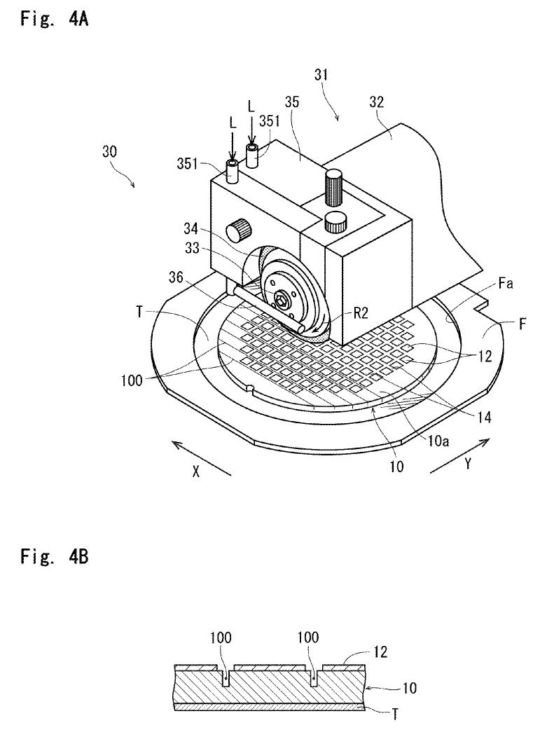

Provided that the forming the protective film is carried out, and the protective film B is formed on the metal portion 121 of the wafer 10, the wafer 10 is transported to a cutting apparatus 30 (only partially shown) shown in FIG. 4A.

The cutting apparatus 30 shown in FIG. 4A includes a chuck table (not shown) for sucking and holding the wafer 10, and a cutting unit 31 for cutting the wafer 10 sucked and held on the chuck table. The chuck table is rotatably configured, and includes an X axis moving unit (not shown) for processing and feeding the chuck table in the direction indicated with an arrow X shown. Further, the cutting unit 31 includes a spindle 33 provided in the Y axis direction indicated with an arrow Y shown, and held rotatably by a spindle housing 32, an annular cutting blade 34 held at the tip of the spindle 33, and a blade cover 35 covering the cutting blade 34, and includes a Y axis moving unit (not shown) for processing and feeding the cutting blade 34 in a Y axis direction. At the blade cover 35, cutting water introducing portions 351 and 351 are formed, and are connected to a cutting water supply source not shown. The cutting water introducing portions 351 and 351 are connected to a pair of cutting water supply nozzles 36 (the opposite side is not visible) disposed so as to interpose the cutting blade 34 from both sides. When cutting water L is introduced from the cutting water introducing portions 351 and 351, the cutting water L is supplied from the pair of cutting water supply nozzles 36 to the processing point at which the wafer 10 is cut by the cutting blade 34. The cutting water L is, for example, pure water, and the spindle 33 is rotatively driven by a spindle motor not shown. The cutting edge configuring the outer periphery of the cutting blade 34 includes, for example, a so-called grindstone in which abrasive grains including diamond or the like are dispersed and fixed by a bonding material such as a metal, resin, or ceramic.

For carrying out the cutting of the present embodiment, first, the wafer 10 is mounted with its front surface 10a facing upward on the chuck table of the cutting apparatus 30, and is sucked and held thereon, so that a division line 14 of the wafer 10 is aligned with the X-axis direction, and alignment with the cutting blade 34 is carried out. Then, the cutting blade 34 rotated at a high speed is positioned to the division line 14 aligned with the X-axis direction, and is allowed to cut thereinto from the front surface 10a side. In addition, the chuck table is processed and fed in the X-axis direction, thereby forming a cut groove 100. Further, the cutting blade 34 of the cutting unit 31 is indexed and fed onto the division line 14 adjacent in the Y-axis direction to the division line 14 including the cut groove 100 formed therein, and not including the cut groove 100 formed therein, thereby carrying out cut processing of forming the cut groove 100 in the same manner as described above. By repeating the procedure, the cut grooves 100 are formed along all the division lines 14 along the X-axis direction. Then, the chuck table is rotated by 90 degrees, and the direction orthogonal to the direction in which the cut groove 100 was formed first is aligned with the X-axis direction. Thus, the cut processing is carried out with respect to all the division lines 14 newly aligned with the X-axis direction, thereby forming the cut grooves 100 along all the division lines 14 formed on the wafer 10. With the procedure up to this point, the cutting of the present embodiment is completed. The cut groove 100 formed at this procedure is a so-called half-cut groove that does not reach the back surface 10b of the wafer 10 as shown in FIG. 4B, and the depth of the cut groove 100 is set at a dimension a little larger than the dimension of the finished thickness for forming a device chip with the wafer 10.

In the cutting, the cutting water L is supplied to the processing point to be processed by the cutting blade 34. At this process, a protective film B is formed at the metal portion 121 exposed on the device 12 of the wafer 10. Accordingly, the metal portion 121 is prevented from being oxidized or etched by the cutting water L supplied to the processing point.

### Removing Protective Film

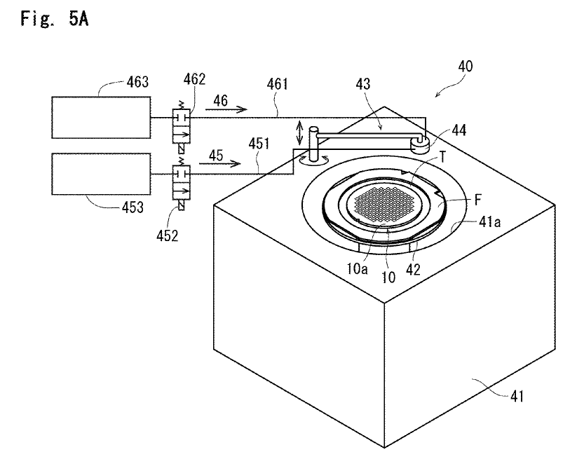

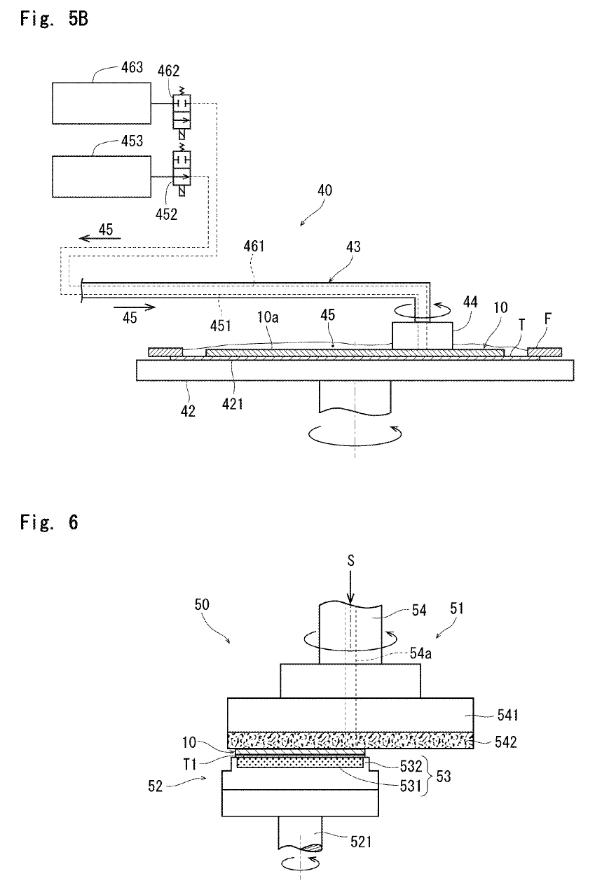

Upon carrying out the cutting, before transporting the wafer 10 to the next process, for example, carrying out hybrid bonding that bonds the surfaces of the wafer 10, removing the protective film B formed on the metal portion 121 is carried out. The removing the protective film can be carried out by various methods, and typically, can be carried out by a protective film removing apparatus 40 shown in FIGS. 5A and 5B.

The protective film removing apparatus 40 is an apparatus for polishing the front surface 10a of the wafer 10, thereby removing the protective film B, and has an apparatus main body 41, a holding unit 42 set at the apparatus main body 41, a polishing washing liquid supply unit 43, a polishing pad 44, an elevating unit for moving up and down the polishing washing liquid supply unit 43 in the vertical direction not shown, and a rotary motor for rotating the holding unit 42 around the axis in parallel with the Z-axis direction not shown as shown in FIGS. 5A and 5B.

The apparatus main body 41 includes opening hole 41a opening in the upper surface. The holding unit 42 holds the wafer 10 subjected to cut processing in the cutting, and is set in the opening hole 41a of the apparatus main body 41. The holding unit 42 is in a disk shape, and a holding surface 421 (see FIG. 5B) for holding the wafer 10 and in parallel with the horizontal direction is formed of a porous ceramic, or the like. The holding surface 421 is connected with a sucking source not shown, and is sucked by the sucking source. As a result, the holding unit 42 sucks and holds the wafer 10 mounted on the holding surface 421.

The polishing washing liquid supply unit 43 supplies a polishing liquid to the wafer 10 held by the holding unit 42. The polishing washing liquid supply unit 43 is set on the upper surface of the apparatus main body 41, is formed in a tube shape extending along the horizontal direction, and is arranged swingably with the proximal end as the center. For the polishing washing liquid supply unit 43, the proximal end is rotated around the axis in parallel with the vertical direction by a motor not shown. The polishing washing liquid supply unit 43 is rotated with the proximal end as the center. As a result, the distal end passes above the wafer 10 held by the holding unit 42. Further, the polishing washing liquid supply unit 43 goes up and down over the descending position in proximity to the front surface 10a of the wafer 10 with the distal end held by the holding unit 42 and the ascending position above the descending position.

The polishing washing liquid supply unit 43 has a first polishing washing liquid supply path 451 and a second polishing washing liquid supply path 461 that are mutually independent inside. The first polishing washing liquid supply path 451 supplies a first polishing washing liquid 45 as a polishing liquid for polishing the wafer 10 held by the holding unit 42, and extends along the longitudinal direction of the polishing washing liquid supply unit 43.

The first polishing washing liquid supply path 451 is connected with a first polishing washing liquid supply source 453 via an opening/closing valve 452, and a first polishing washing liquid 45 is supplied from the first polishing washing liquid supply source 453. The polishing washing liquid supply unit 43 is positioned at the descending position by an elevating unit, and is swung with the proximal end as the center. As a result, the first polishing washing liquid supply path 451 supplies the first polishing washing liquid 45 supplied from the first polishing washing liquid supply source 453 from the distal end of the polishing washing liquid supply unit 43 onto the front surface 10a of the wafer 10 held by the holding unit 42. Incidentally, in an embodiment shown, the first polishing washing liquid 45 is a slurry including a solution having acidity or alkalinity, and abrasive grains. Incidentally, the abrasive grains include silica particles, or the like.

The second polishing washing liquid supply path 461 supplies a second polishing washing liquid 46 as a polishing liquid different from the first polishing washing liquid 45 onto the wafer 10 held by the holding unit 42. The second polishing washing liquid supply path 461 extends along the longitudinal direction of the polishing washing liquid supply unit 43. The second polishing washing liquid supply path 461 is connected with a second polishing washing liquid supply source 463 via an opening/closing valve 462, and the second polishing washing liquid 46 is supplied from the second polishing washing liquid supply source 463. The polishing washing liquid supply unit 43 is positioned at the descending position by an elevating unit, and is swung with the proximal end as the center. As a result, the second polishing washing liquid supply path 461 supplies the second polishing washing liquid 46 supplied from the second polishing washing liquid supply source 463 from the distal end of the polishing washing liquid supply unit 43 onto the front surface 10a of the wafer 10 held by the holding unit 42. Incidentally, in the present embodiment, the second polishing washing liquid 46 includes pure water and a washing liquid.

The polishing pad 44 comes in contact with the wafer 10 onto which the first and second polishing washing liquids 45 and 46 have been supplied from the polishing washing liquid supply unit 43, and polishes/washes the wafer 10. The polishing pad 44 is formed in the shape of a disk with a smaller diameter than that of the wafer 10, and includes a material such as a nonwoven fabric or foamed urethane in an embodiment shown. The polishing pad 44 is supported rotatably around the axis in parallel with the vertical direction by the distal end of the polishing washing liquid supply unit 43, and can come in contact with the front surface 10a of the wafer 10 sucked and held by the holding surface of the holding unit 42 upon positioning of the polishing washing liquid supply unit 43 at the descending position. As shown in FIG. 5B, the polishing pad 44 communicates with the first and second polishing washing liquid supply paths 451 and 461, and has an opening at the lower surface, and supplies the first and second polishing washing liquids 45 and 46 supplied from the first and second polishing washing liquid supply paths 451 and 461, respectively, onto the front surface 10a of the wafer 10.

The protective film removing apparatus 40 roughly includes the foregoing configuration. In the removing the protective film to be carried out after the cutting, the wafer 10 subjected to cut processing by the cutting is transported to the protective film removing apparatus 40, and the back surface 10b side of the wafer 10 is mounted on the holding surface 421 of the holding unit 42 via a tape T, to be sucked and held thereon, and the polishing washing liquid supply unit 43 is moved down to a prescribed descending position.

In the removing the protective film of the present embodiment, as shown in FIG. 5B, while supplying the first polishing washing liquid 45 from the first polishing washing liquid supply source 453 to the front surface 10a of the wafer 10 through the first polishing washing liquid supply path 451 and the polishing pad 44 by opening the opening/closing valve 452 for a prescribed time, the holding unit 42 is rotated around the axis, and the proximal end of the polishing washing liquid supply unit 43 is swung, and the polishing pad 44 is brought into contact with the front surface 10a of the wafer 10.

As a result of this, the first polishing washing liquid 45 flows from the center toward the outer edge on the front surface 10a of the wafer 10. In addition, the polishing pad 44 slides on the front surface 10a of the wafer 10, and polishes the front surface 10a of the wafer 10, and washes the front surface 10a of the wafer 10. Then, the holding unit 42 is rotated for a prescribed time, thereby supplying the first polishing washing liquid 45 through the first polishing washing liquid supply path 451. Then, the opening/closing valve 452 is closed, thereby the supply of the first polishing washing liquid 45 is stopped.

As described above, after carrying out polishing/washing of the front surface 10a of the wafer 10 by the first polishing washing liquid 45, while supplying the second polishing washing liquid 46 different from the first polishing washing liquid 45 onto the front surface 10a of the wafer 10, the front surface 10a of wafer 10 is polished by the polishing pad 44, thereby washing the front surface 10a of the wafer 10. More specifically, while supplying the second polishing washing liquid 46 from the second polishing washing liquid supply source 463 to the front surface 10a of the wafer 10 through the second polishing washing liquid supply path 461 and the polishing pad 44 by opening the opening/closing valve 462 for a prescribed time, and, while rotating the holding unit 42 around the axis, the proximal end of the polishing washing liquid supply unit 43 is swung, and the polishing pad 44 is brought into contact with the front surface 10a of the wafer 10. Then, the second polishing washing liquid 46 flows from the center toward the outer edge on the front surface 10a of the wafer 10. In addition, the polishing pad 44 slides on the front surface 10a of the wafer 10, and the polishing pad 44 washes the front surface 10a of the wafer 10 while polishing the front surface 10a of the wafer 10. With such washing, for a prescribed time, the holding unit 42 is rotated, and the second polishing washing liquid 46 is supplied through the second polishing washing liquid supply path 461, and then, the rotation of the holding unit 42 and the swinging of the polishing washing liquid supply unit 43 are stopped, and the opening/closing valve 462 is closed to stop the supply of the second polishing washing liquid 46. In addition, the distal end of the polishing washing liquid supply unit 43 is retreated from above the holding unit 42, and the holding unit 42 is moved up, and is positioned at the ascending position. By carrying out the polishing/washing treatment up to this point, the protective film B formed at the metal portion 121 of the device 12 on the front surface 10a of the wafer 10 is removed. Thus, the metal portion 121 configuring the electrode of the device 12 is exposed, and the removing the protective film is completed, resulting in the completion of the processing method of a workpiece of the present embodiment.

In accordance with the processing method of a workpiece, even when the method includes a cutting of carrying out cut processing while supplying cutting water L to the workpiece (wafer 10), it will not cause an oxidation/etching phenomenon in the metal portion of the device. As a result of this, when the wafers 10 are bonded together to form a lamination wafer, or the wafer 10 is divided to form device chips, followed by bonding and joining of the two devices, proper hybrid bonding can be carried out. Incidentally, with the protective film removing apparatus 40, two types of polishing liquids, namely, the first polishing washing liquid 45 and the second polishing washing liquid 46 were supplied, thereby polishing the front surface 10a of the wafer 10. However, the present disclosure is not limited thereto. It is also acceptable that one kind of polishing liquid removes the protective film.

The embodiment was configured as follows: even when a forming the protective film in which the protective film forming apparatus 20 supplies the protective film forming solution W containing an anticorrosive to the front surface 10a side of the wafer 10, thereby forming the protective film B on the metal portion 121 was carried out, and then, cutting water L is supplied to the processing point on the wafer 10 in the cutting, the metal portion 121 is prevented from being oxidized, or etching is prevented from being generated in the metal portion 121. However, the present disclosure is not limited thereto. For example, the following is also acceptable: with the cutting apparatus 30 for carrying out the cutting, the cutting water L to be introduced from the cutting water introducing portions 351 and 351 is mixed with the protective film forming solution W containing the anticorrosive, and the resulting mixture is supplied from the cutting water supply nozzle 36 to the processing point at the cutting. This enables the formation of the protective film B on the metal portion 121 of the device 12 of the wafer 10 without using the protective film forming apparatus 20. In this case, the forming the protective film is carried out simultaneously with the cutting.

Incidentally, the removing the protective film included in the processing method of a workpiece of the disclosure is not limited to the method for polishing the front surface 10a of the wafer 10 by the protective film removing apparatus 40, and may be carried out by other aspects. For example, the following is also acceptable: the wafer 10 subjected to the cutting is transported to a polishing apparatus 50 (only partially shown) shown in FIG. 6, thereby carrying out the removing the protective film.

The polishing apparatus 50 shown in FIG. 6 includes at least a polishing unit 51 for polishing the wafer 10, and a holding unit 52 for holding the wafer 10. The polishing unit 51 includes a rotary shaft 54 to be rotated by a rotary motor not shown, a polishing wheel 541 set at the lower end of the rotary shaft 54, and a polishing pad 542 mounted at the lower surface of the polishing wheel 541, and is configured such that a polishing liquid (slurry) S can be introduced from a polishing liquid supply unit not shown via a path 54a (indicated with a broken line) formed at the axis of the rotary shaft 54. As the polishing liquid S, a known polishing liquid can be used. For example, the polishing liquid S is formed by mixing appropriate abrasive grains in a solution having acidity or alkalinity. The holding unit 52 includes a chuck table 53 whose rotary shaft 521 is rotated by a rotary motor not shown. The chuck table 53 includes a holding surface 531 including a porous member having air permeability, and a frame part 532 for enclosing the holding surface 531. The frame part 532 is connected with a sucking source not shown, so that the sucking source is operated, thereby generating a negative pressure on the holding surface 531.

When the removing the protective film is carried out by the polishing apparatus 50, a tape T1 having the same shape as that of the wafer 10 is prepared, and is bonded to the back surface 10b side of the wafer 10. Then, the tape T1 side of the wafer 10 is mounted on the chuck table 53 of the holding unit 52, and a negative pressure is generated on the holding surface 531 for adsorption and holding. Then, the chuck table 53 is rotated at a prescribed rotation speed, and the polishing unit 51 is positioned on the wafer 10. In addition, the rotary shaft 54 is rotated by a rotary motor not shown, and while supplying the slurry S for a prescribed time, the front surface 10a of the wafer 10 is polished by the polishing pad 542. Even such polishing processing can remove the protective film B formed on the metal portion 121 of the device 12 of the wafer 10.

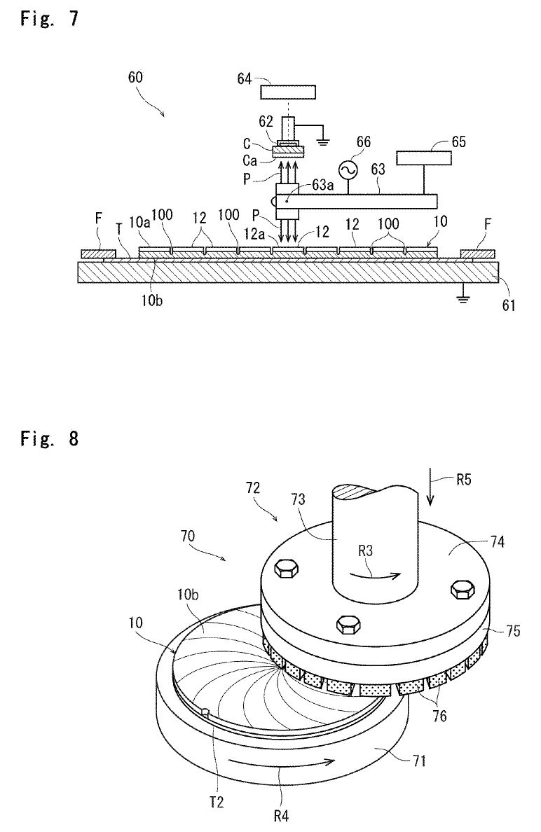

Further, the removing the protective film of the present disclosure can also be carried out using a protective film removing apparatus 60 (only partially shown) shown in FIG. 7 using a plasma generator. Particularly, when at the forming the protective film, a Cu₂O film is formed as the protective film B at the metal portion 121 of the device 12, it is possible to activate the surface and remove the protective film B using the protective film removing apparatus 60 described below. When the protective film B is removed using the protective film removing apparatus 60 shown, the wafer 10 held at the frame F is transported to the protective film removing apparatus 60 via the tape T subjected to cut processing by the cutting.

The protective film removing apparatus 60 shown in FIG. 7 includes a chuck table 61 for holding the wafer 10 including cut grooves 100 formed by the cutting therein, a sucking member 62 for holding a semiconductor chip C manufactured by another chip manufacturing method on the wafer 10 held by the chuck table 61, and a plasma generator 63 for generating an atmospheric plasma, and is configured so as to enable a bonding described later to be carried out at the same time. The chuck table 61 is configured such that the holding surface is caused to communicate with a sucking source not shown, thereby sucking and holding the wafer 10.

Then, as shown in FIG. 7, the back surface 10b of the wafer 10 is sucked and held onto the chuck table 61 via the tape T, and the frame F is held by a clamp not shown. As a result of this, the wafer 10 is fixed to the chuck table 61 with its front surface 10a exposed upward.

Then, on the wafer 10 side, the device 12 to be joined with the semiconductor chip C is selected. The sucking member 62 is grounded, and is configured to be able to communicate with the sucking source 64. When the removing the protective film of the present embodiment is carried out, the sucking member 62 sucks and holds the semiconductor chip C previously transported to a prescribed storage site from the back surface side. Namely, the semiconductor chip C is sucked and held with the side of the surface Ca that is the bonding surface exposed downward by the sucking member 62. Then, the sucking member 62 is disposed above the device 12 to be bonded with the sucked and held semiconductor chip C.

The plasma generator 63 is connected with a plasma gas supply source 65 for supplying a rare gas such as an argon gas or a helium gas, and a high frequency power supply 66. Then, the tip 63a of the plasma generator 63 is disposed between the semiconductor chip C held by the sucking member 62 and the prescribed device 12 of the underlying wafer 10. Further, the plasma generator 63 generates an atmospheric plasma P using a rare gas and a high frequency electric power, and irradiates with the atmospheric plasma P from its tip in the vertical direction.

As a result of this, the atmospheric plasma P is irradiated to the surface Ca of the semiconductor chip C, so that the surface Ca of the semiconductor chip C is activated. Along with this, the atmospheric plasma P is irradiated to the front surface 12a of a prescribed device 12 of the wafer 10. Thus, the protective film B formed at the metal portion 121 of the front surface 12a of the device 12 is removed, and the semiconductor (silicon) part and the metal portion 121 configuring the device 12 are activated. In this way, with the protective film removing apparatus 60 using a plasma, it is possible to remove the protective film B formed at the forming the protective film, and to activate the surface of the device 12. Herein, at the surface Ca on the device side of the semiconductor chip C and the front surface 12a of the device 12 of the wafer 10, silicon (Si) forming the device and copper forming the metal portion 121 functioning as an electrode are exposed. Then, by activating the above, a nitride film such as SiON or SiN, and an oxide film such as SiO₂ are formed on the surface Ca of the semiconductor chip C and the front surface 12a of the device 12. Accordingly, a bonding described later is preferably carried out (the bonding will be described later). As described above, when the protective film B is formed of a Cu₂O film, using the protective film removing apparatus 60, the protective film B is properly removed in the process of activating the surface Ca of the semiconductor chip C, and the front surface of the device 12 to prepare for bonding of the semiconductor chip C and the device 12. In this way, use of the protective film removing apparatus 60 including the plasma generator 63 also allows the removing the protective film to be preferably carried out.

Incidentally, the following example was described: at the removing the protective film, the atmospheric plasma P is irradiated using the protective film removing apparatus 60, so that the protective film B formed at the metal portion 121 is removed; in addition, the semiconductor (silicon) part and the metal portion 121 configuring the device 12 were activated. However, for example, the removing the protective film of the present disclosure may be carried out by the following vacuum plasma treatment: a vacuum is created in the treatment space, and further, ionized ions, electrons, and radicals generated in the plasma state are brought into contact with the surface Ca on the device side of the semiconductor chip C and the front surface 12a of the device 12 of the wafer 10. Further, the removing the protective film of the present embodiment may be carried out by performing UV treatment processing in which a low-wavelength ultraviolet rays (UV) are irradiated to the surface Ca on the device side of the semiconductor chip C and the front surface 12a of the device 12 of the wafer 10.

The processing method of a workpiece of the present disclosure is not limited to the foregoing configuration. More specifically, the following has been described: in the description of the embodiment, the processing method of a workpiece of the present embodiment includes a forming the protective film, a cutting, and a removing the protective film. However, the method of processing a workpiece of the present embodiment is not limited to including only the three procedures described above, but also includes adding other processing in addition to the three procedures to constitute the method of processing a workpiece. For example, the method may include a grinding of grinding and thinning the back surface 10b of the wafer 10 after the cutting and before carrying out the removing the protective film. Further, as described by reference to FIGS. 5A, 5B, and 6, the following is also acceptable: the polishing liquid is supplied, and the front surface 10a of the wafer 10 is polished by the polishing pad, thereby removing the protective film B; then, the atmospheric plasma P is supplied to the surface of each device 12 using the protective film removing apparatus 60 described by reference to FIG. 7 in order to activate the front surface 12a of the device 12; as a result, the front surface 12a of the device 12 is activated.

Then, a description will be given to an embodiment in accordance with the method for manufacturing a semiconductor device configured on the basis of the present disclosure. The method for manufacturing a semiconductor device described below is a method for manufacturing a semiconductor device in which the substrate including devices respectively formed in regions partitioned by a plurality of crossing division lines is divided to form device chips, and then, device surfaces are bonded with each other.

The method for manufacturing a semiconductor device of the present embodiment includes a procedure configuring the processing method of a workpiece, and a detailed description of the procedures already described in the description of the embodiment will be appropriately omitted. Incidentally, the workpiece to be processed with the method for manufacturing a semiconductor device of the present embodiment described below is the wafer 10 described by reference to FIG. 1 in connection with the processing method of a workpiece, and is the wafer including a plurality of devices 12 formed on the front surface 10a partitioned by the division lines 14. Then, respective device surfaces of the device chips manufactured from the wafer 10, and semiconductor chips (e.g., the semiconductor chip C shown in FIG. 7) manufactured from a semiconductor wafer not shown are bonded, thereby carrying out so-called hybrid bonding. As a result, one semiconductor device is manufactured.

### Forming the Protective Film

For carrying out a method for manufacturing a semiconductor device of the present embodiment, a forming a protective film on the metal portion exposed on the device of a substrate is carried out. The forming the protective film is carried out in the same manner as with the forming the protective film in the processing method of a workpiece described with reference to FIG. 2, and a detailed description thereof is omitted. With the forming the protective film, by the various methods described above, it is possible to supply and apply a protective film forming solution W containing an anticorrosive onto the front surface 10a side of the wafer 10, so that the protective film B is formed on the metal portion 121.

### Cutting

Then, a cutting in which while supplying the cutting water L along the division line, the division line is cut by a cutting blade is carried out. The cutting can also be carried out in the same manner as with the cutting in the processing method of a workpiece described with reference to FIGS. 4A and 4B. Cutting processing is performed from the front surface 10a side of the wafer 10, thereby forming a cut groove 100 shown in FIG. 4B. In the cutting, first, the protective film B has been formed on the metal portion 121 of the device 12 of the wafer 10. Accordingly, even when the cutting water L is supplied to the processing point to be subjected to cutting processing, the metal portion 121 of the device 12 is prevented from being oxidized, or from being etched.

### Grinding

With the method for manufacturing a semiconductor device of the present embodiment, in order to divide the wafer 10 and to form device chips, after the cutting, a grinding described below is carried out. Incidentally, in the cutting, a tape T was bonded to the back surface 10b of the wafer 10 and the annular frame F, so that the wafer 10 was held by the frame F. However, for carrying out a grinding described below, a tape T2 (see FIG. 8) is bonded to the front surface 10a side of the wafer 10 in advance, and the tape T on the back surface 10b is removed together with the frame F, thereby exposing the back surface 10b side.

The wafer 10 on which the cutting has been performed as described above is transported to a grinding apparatus 70 (only partially shown) shown in FIG. 8. As shown in FIG. 8, the grinding apparatus 70 has a grinding unit 72 for grinding and thinning the back surface 10b of the wafer 10 sucked and held onto the chuck table 71. The grinding unit 72 includes a rotary spindle 73 to be rotated by a rotation driving mechanism not shown, a wheel mount 74 mounted at the lower end of the rotary spindle 73, and a grinding wheel 75 attached to the lower surface of the wheel mount 74, and a plurality of abrasive grind wheels 76 are disposed at the lower surface of the grinding wheel 75.

The wafer 10 is transported to the grinding apparatus 70 shown in FIG. 8, and is mounted on the chuck table 71 with the back surface 10b facing upward, and is sucked and held thereby. Then, while rotating the rotary spindle 73 of the grinding unit 72 in the direction indicated with an arrow R3 in FIG. 8, for example, at 3000 rpm, the chuck table 71 is rotated in the direction indicated with an arrow R4, for example, at 300 rpm. Then, while supplying grinding water onto the back surface 10b of the wafer 10 by a grinding water supply unit not shown, the abrasive grind wheel 76 is brought into contact with the back surface 10b of the wafer 10, and the grinding wheel 75 is grinding-fed downward indicated with an arrow R5 shown at a grinding feed speed of, for example, 1 μm/sec. At this procedure, grinding can be advanced while measuring the thickness of the wafer 10 by a measuring instrument not shown. Thus, the back surface 10b of the wafer 10 is ground in a prescribed amount, thereby setting the thickness of the wafer 10 to a prescribed thickness. Then, the grinding unit 72 is stopped, and the grinding of grinding the back surface 10b of the wafer 10 is completed through washing and drying, and the like. By carrying out the grinding, the cut groove 100 formed by the cutting is exposed on the back surface 10b side (not shown). As a result of this, the wafer 10 is divided on a per-device 12 basis, resulting in the formation of device chips.

### Removing Protective Film

Upon carrying out the grinding, a removing a protective film in which a tape T is bonded to the back surface 10b side of the wafer 10, and the wafer 10 is held by the annular frame F, thereby removing the protective film B is carried out. The removing the protective film of the present embodiment can be carried out in the same manner as with the removing the protective film of the processing method of a workpiece described by reference to FIGS. 5A and 5B to 7. Incidentally, although the details thereof will be omitted, when the removing the protective film described by reference to FIGS. 5A and 5B to 7 in the present embodiment is carried out, the wafer 10 is divided into individual device chips on a per-device 12 basis. In this respect, the removing the protective film of the present embodiment is different from the processing method of a workpiece. Then, when the protective film B formed at the forming the protective film is formed of one or more kind of the anticorrosive components, it is favorable to remove the protective film B by polishing the front surface 10a side of the wafer 10 by a polishing pad while supplying a polishing liquid as described by reference to FIGS. 5A and 5B, and 6. Further, when the protective film B is formed of a Cu₂O film, it is possible to activate the front surface 12a of the device 12 using a plasma generator 63 of the protective film removing apparatus 60 described by reference to FIG. 7, and to remove the protective film B. Accordingly, it is preferable to carry out the removing the protective film using the protective film removing apparatus 60 shown in FIG. 7.

Further, when at the forming the protective film, the protective film B is formed of one or more kind of the anticorrosive components on the metal portion 121 of the device 12, and at the removing the protective film, the protective film B is removed by a polishing pad while supplying a polishing liquid, an anticorrosive for forming a Cu₂O film on the metal portion 121 may be mixed with the polishing liquid to be supplied at the removing the protective film. In this way, even when the protective film B is removed at the removing the protective film, the top of the metal portion 121 is prevented from being oxidized or etched by the supplied polishing liquid. In addition, the atmospheric plasma P is supplied using the plasma generator 63 in order to activate the front surface 12a of the device 12, which can remove the Cu₂O film, and it becomes possible to protect the metal portion 121 until immediately before bonding the device surfaces, and manufacturing a semiconductor device. From the foregoing viewpoint, most preferably, at the forming the protective film, the protective film B including a Cu₂O film is formed, and the protective film removing apparatus 60 shown in FIG. 7 is used, thereby carrying out the removing the protective film.

### Bonding

As described above, upon carrying out the removing the protective film, a bonding of bonding the device surfaces of a device chip is carried out. The device surface of the device chip is the front surface 12a on which the metal portion 121 is formed in the device chip formed by dividing the device 12. As described above, typically, the removing the protective film described with reference to FIG. 7 is carried out in the case where the protective film B is formed of a Cu₂O film. Alternatively, even when the protective film B is formed of one or more kind of the anticorrosive components, and the protective film B is removed by polishing, the atmospheric plasma P is supplied to the device surface for activation using the protective film removing apparatus 60 shown in FIG. 7 in order to activate the front surface 12a of the device 12. At this procedure, as described in connection with FIG. 7, the semiconductor chip C formed by dividing the same semiconductor wafer as the wafer 10 is positioned, and is positioned in a face-to-face manner to the opposing surface of the device chip 12 to be bonded such that the device surfaces are opposed to each other. Thus, the atmospheric plasma P is supplied to the device surfaces of both, so that the opposed device surfaces are activated.

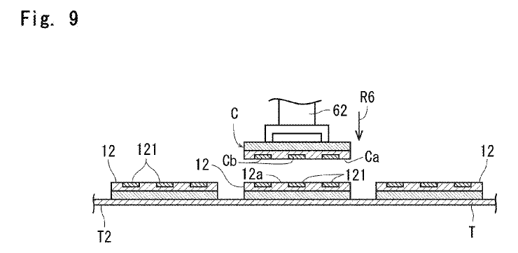

Then, as shown in FIG. 9, the surface Ca of the semiconductor chip C and the divided device 12 are opposed to each other, and are bonded with each other. Namely, at the bonding, as shown, the sucking member 62 holding the semiconductor chip C with the surface Ca activated by the protective film removing apparatus 60 moves down as indicated with an arrow R6. As a result of this, the surface Ca of the semiconductor chip C is pressed against the activated front surface 12a of the underlying device 12. As a result of this, the surface Ca of the semiconductor chip C and the front surface 12a of the device 12 are hybrid bonded with each other, so that the electrode Cb of the semiconductor chip C and the metal portion 121 of the device chip 12 are also connected with each other. Incidentally, in the foregoing description, a description has been given to the following: irradiation of the atmospheric plasma P by the protective film removing apparatus 60 shown in FIG. 7 can carry out the removing the protective film, and can activate the surface Ca of the semiconductor chip C and the front surface 12a of the device 12. However, also by carrying out the vacuum plasma process and UV treatment process on the surface Ca of the semiconductor chip C and the front surface 12a of the device 12, it is possible to activate the front surface 12a of the device 12 and the surface Ca of the semiconductor chip C. Also by performing a vacuum plasma process and a UV treatment process in place of the irradiation of the atmospheric plasma P by the protective film removing apparatus 60, it is possible to preferably implement the bonding.

As described above, the surface Ca of the semiconductor chip C and the front surface 12a of the device 12 are activated, in addition to copper. As a result, nitride films such as SiON and SiN, and an oxide film such as SiO₂ are formed. Therefore, the surface Ca of the semiconductor chip C and the front surface 12a of the device 12 are pressed against each other, resulting in bonding between oxide films (or nitride films). As a result, the surface Ca and the front surface 12a of the device 12 are firmly joined with each other.

With the method for manufacturing a semiconductor device of the present embodiment, at the forming the protective film, a protective film forming solution W containing an anticorrosive is applied, thereby forming the protective film B on the metal portion 121 of the device 12. Accordingly, even when cut processing or grinding processing is performed with the protective film B formed, the metal portion 121 is protected by the protective film B, which prevents the metal portion 121 from being oxidized or etched. Then, before carrying out the bonding, the protective film B is removed, and then, the devices are bonded with each other. Accordingly, unevenness at the bonding surfaces is not generated, so that a semiconductor device with the device surfaces of two device chips firmly joined with each other is formed.

In the embodiment, the example in which the electrode of the device 12 was formed of copper (Cu) was shown. However, the present disclosure is not limited thereto. The metal portion 121 may be formed of nickel (Ni), or cobalt (Co). Further, other metals capable of configuring an electrode are also acceptable.

### REFERENCE SIGNS LIST

10 Wafer

12 Device

14 Division line

20 Protective film forming apparatus

22 Chuck table

24 Supply nozzle

30 Cutting apparatus

31 Cutting unit

32 Spindle housing

33 Spindle

34 Cutting blade

35 Blade cover

351 Cutting water introducing portion

36 Cutting water supply nozzle

40 Protective film removing apparatus

41 Apparatus main body

41a Opening hole

42 Holding unit

421 Holding surface

43 Polishing washing liquid supply unit

44 Polishing pad

45 First polishing washing liquid

451 First polishing washing liquid supply path

452 Opening/closing valve

453 Polishing washing liquid supply source

46 Second polishing washing liquid

461 Second polishing washing liquid supply path

462 Opening/closing valve

463 Polishing washing liquid supply source

50 Polishing apparatus

51 Polishing unit

52 Holding unit

53 Chuck table

54 Rotary shaft

541 Polishing wheel

542 Polishing pad

60 Protective film removing apparatus

61 Chuck table

62 Sucking member

63 Plasma generator

64 Sucking source

65 Plasma gas supply source

70 Grinding apparatus

71 Chuck table

72 Grinding unit

100 Cut groove

C Semiconductor chip

### F Frame

L Cutting water

P Atmospheric plasma

T, T1, T2 Tape

W Protective film forming solution

What is claimed is:

1. A method for processing a workpiece, comprising:
forming a protective film on a metal portion exposed at a surface of the workpiece;
cutting by a cutting blade while supplying cutting water to the workpiece; and
removing the protective film,
wherein at the forming the protective film,
the protective film is formed on the metal portion by supplying a protective film forming solution containing an anticorrosive.

2. The method for processing a workpiece of claim 1, wherein
carrying out the cutting and the forming the protective film at the same time by including the protective film forming solution in the cutting water to be supplied to a processing point at the cutting.

3. The method for processing a workpiece of claim 1, wherein
the removing the protective film is performed by polishing the surface of the workpiece by a polishing pad, and thereby removes the protective film.

4. The method for processing a workpiece of claim 1, wherein
the removing the protective film is performed by irradiating with a plasma to the surface of the workpiece, and thereby removes the protective film.

5. A method for manufacturing a semiconductor device, in which a substrate including devices respectively formed in regions partitioned by a plurality of crossing division lines is divided to form device chips, and then, device surfaces are bonded with each other, the method comprising:
forming a protective film on a metal portion exposed on the device of a substrate;
cutting the substrate by a cutting blade while supplying cutting water along the division lines of the substrate;
grinding and thinning a surface of the substrate opposite to a surface on which the device is formed by a grinding wheel;
removing the protective film; and
bonding the device surfaces of the device chips, wherein
the forming the protective film is performed by suppling a protective film forming solution containing an anticorrosive, and thereby forms a protective film on the metal portion of the device.
